(19) United States
(12) Patent Application Publication
(10) Pub. No.: US 2004/0105239 A1
(43) Pub. Date: Jun. 3, 2004

(54) Optical transceiver connection module

(76) Inventor: Tu Kuo Chiang, Taoyuan (TW)

Correspondence Address: BIRCH STEWART KOLASCH & BIRCH, PO BOX 747, FALLS CHURCH, VA, 22040-0747, US

(21) Appl. No.: 10/353,965

(22) Filed: Jan. 30, 2003

(30) Foreign Application Priority Data
Nov. 29, 2002 (TW) 091219277

(51) Int. Cl. H05K 7/00; G02B 6/36

(52) U.S. Cl. 361/728; 385/88; 385/92

(57) ABSTRACT

An optical transceiver connection module is provided for connecting an optical transceiver with a fiber optic connector of a different type. The connection module comprises a housing of a first-type optical transceiver and an adapter. The housing has a first-type connection port so that a connector of the same type can be plugged in. The adapter is attached to the first-type connection port of the housing and has a second-type connection port for a second-type connector to be plugged in.

### BACKGROUND OF THE INVENTION

1. Field of Invention

The invention relates to an optic fiber connection module and, in particular, to a connection structure between an SC optical transceiver and the SC- and MU-type fiber connectors.

2. Related Art

Currently, the standards of optical transceivers and fiber connectors on the market are defined by each manufacturer. Therefore, they are often incompatible with one another. In other words, the optical transceivers and fiber connectors made by each manufacturer have one-to-one correspondence. Such examples include the Lucent connect (LC) developed by Bell Laboratory, the former Lucent Tech., Inc, the miniature unit (MU) of NTT, Inc., and the SC commonly used in North America. Any of the above-mentioned fiber connector cannot be connected with other types of optical transceiver. This problem results from market competition. In order to increase their market occupancy, the manufacturers are forced to design the connection ports of their optical transceivers in such a way to comply with the connector standards of their own. However, this results in great troubles for manufacturers that make optical communication devices and optic fiber networks.

Therefore, there are adapters for connecting different types of optical devices. For example, the MU/SC adapter made by Bullwill, Inc. is designed for connecting MU and SC connectors. However, it is still inconvenient to use the adapters. For instance, one has to purchase optical cables with MU connectors on both ends and an adapter in order to connect an SC connector and an MU optical transceiver. Even a professional optic fiber network engineer can only remove the SC connectors and put in an MU connector at each optic cable terminal. This requires one to have all the elements and installation tools for the MU connector. Therefore, adaptors are obviously ineffective for the installation of a local optic fiber network or even achieving the goal of fiber to the desk (FTTD). Moreover, they often increase the cost.

### SUMMARY OF THE INVENTION

In view of the foregoing, it is an objective to provide an optical transceiver connection module that is applicable to the connection between an SC optical transceiver and the SC- and MU-type fiber connectors.

To achieve the above-mentioned objective, the disclosed optical transceiver connection module includes a housing and an adapter. The housing covers a first-type optical transceiver and has a first-type connection port for the connection with a connector of the same type. The adapter is attached to the first-type connection port of the housing and has a second-type connection port for a second-type connector to be plugged in. In this method, the first-type optical transceiver and the second-type fiber connector can be connected.

### BRIEF DESCRIPTION OF THE DRAWINGS

The invention will become more fully understood from the detailed description given hereinbelow illustration only, and thus are not limitative of the present invention, and wherein:

FIG. 1 is a three-dimensional view of a preferred embodiment of the disclosed optical transceiver connection module;

FIG. 2 is a three-dimensional view of the module depicted in FIG. 1 in connection with a MU connector;

FIG. 3 is a local exploded view of the module depicted in FIG. 1 in connection with an MU connector; and

FIG. 4 is a three-dimensional view of the module depicted in FIG. 1 in connection with an SC connector.

### DETAILED DESCRIPTION OF THE INVENTION

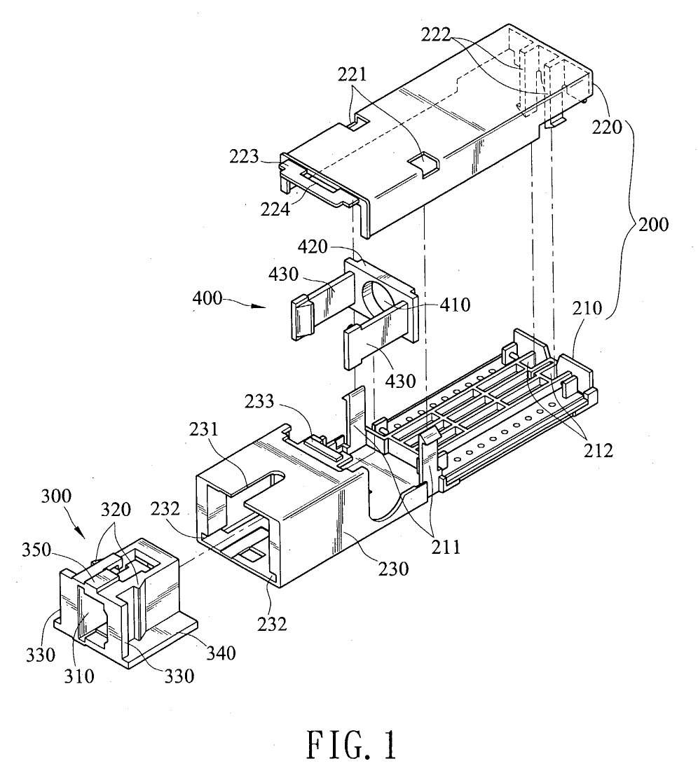

Please refer to FIG. 1. An optical transceiver connection module 100 enables a SC optical transceiver to be connected with SC- and MU-type fiber connectors. The optical transceiver connection module 100 includes a housing 200 that covers the optical transceiver (not shown), an adapter 300, and a connection element 400.

The rectangular housing 200 consists of a first cover 210 and a second cover 220. The front end (as shown in the drawing) of the first cover 210 is a complete SC connection port 230. The top surface of the input end has a positioning hole 231. The inner side of the bottom of the SC connection port 230 has grooves 232 formed on both sides. The top surface at the back end of the SC connection port 230 has a protruding block 233. The rest structure of the SC connection port 230 is roughly the same as in the prior art and, therefore, is not further described herein. Both sides of the first cover 210 have two hook arms 211 extending upward, with hooks at their tails. The back end of the first cover 210 has two hook holes 212. The front end of the second cover 220 has a fin 223 extending forward. The fin 223 is formed with a plugging hole 224 that matches with the protruding block 233 on the back top surface of the SC connection port 230. Both sides of the second cover 220 have two hook holes 221 that match with the two hook arms 211 of the first cover 210. The back end of the second cover 220 has two hook arms 222 that match with the two hook holes 212 of the first cover 210.

The adapter 300 has a rectangular hollow main body. It has an MU connection port 310. Since the rest structure of the adapter 300 is roughly the same as the prior and, therefore, is not further described herein. The outer side of the adapter has protruding blocks 320 on both sides. The front end is formed with a side plate 330. The bottom is a bottom plate 340 extending horizontally to both sides. The top end is formed with a rectangular positioning block 350.

The connection element 400 is a plate 420 with a through hole 410 formed on the rear end. The front end has two parallel hook arms 430 extending forward. The tails of the hook arms 430 are hooks facing each other.

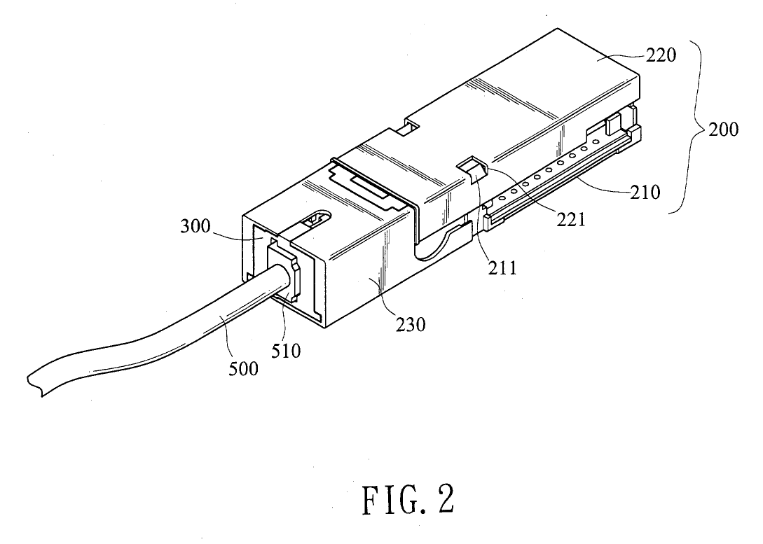

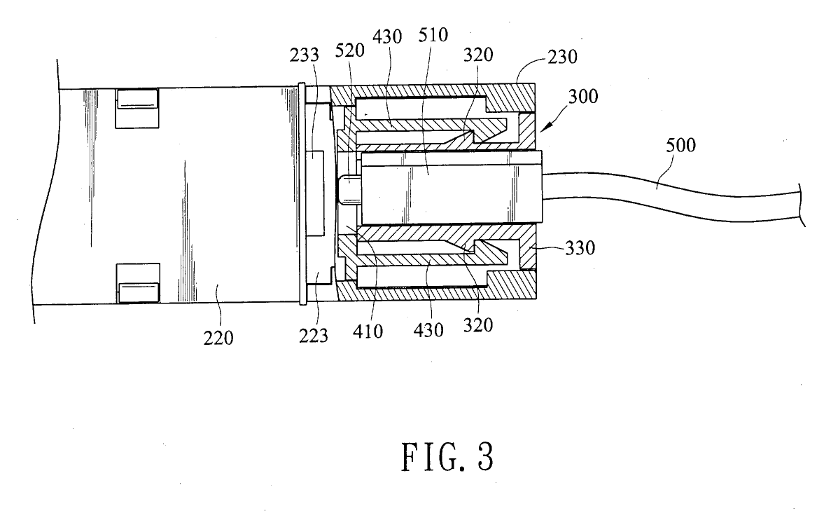

Please refer to FIGS. 2 and 3 for the assembly method when using the invention to connect MU connectors. The positioning block 350 on the top of the adapter 300 is aligned with the positioning hole 231 at the SC connection port 230 of the first cover 210. Both ends of the bottom plate 340 are aligned with the two grooves 232 of the SC connection port 230. The adapter 300 is thus embedded in the SC connection port 230 of the first cover 210. The connection element 400 is inserted from the other side of the SC connection port 230. The hooks of the two hook arms 430 are connected to the blocks 320 on both sides of the adapter 300. Finally, the MU connector 510 in front of the optic cable 500 is inserted into the MU connection port 310 of the adapter 300. In practice, one of course needs to have the optic fibers 520 in the optic cable penetrate through the through hole 410 of the connection element 400 and electrically connect with the photo sensor on the circuit board of the optical transceiver inside the housing 200. In the end, the first cover 210 and the second cover 220 are combined. Since this is not the essence of the invention, it is not described in further detail hereinafter.

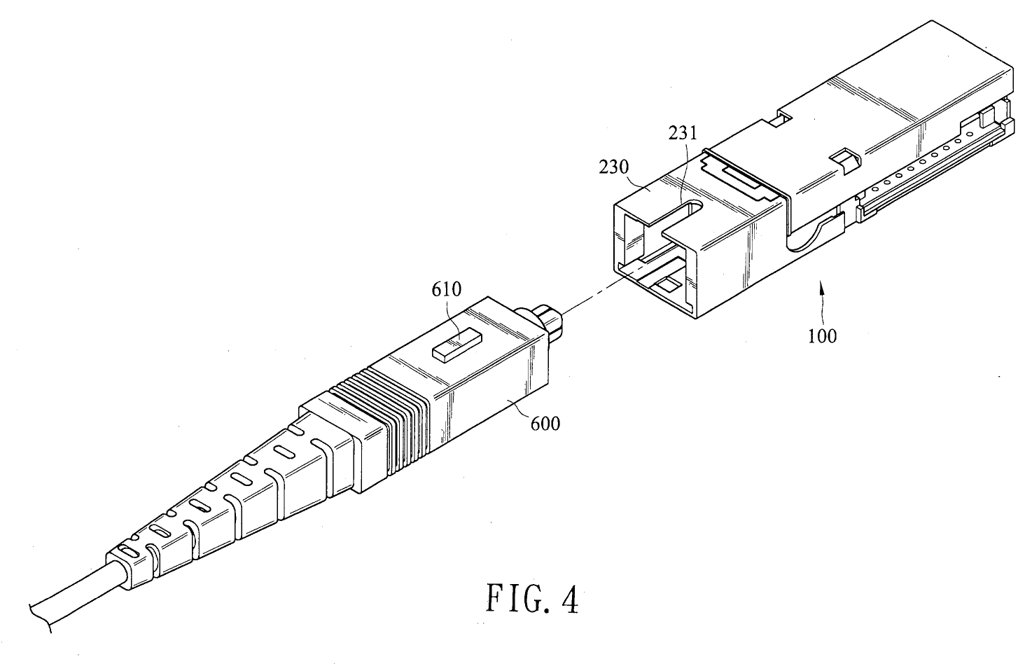

FIG. 4 shows the assembly method of applying the invention to the same-type SC connectors. In this case, one does not need to assemble the connection element and the adapter. The positioning block 610 of the SC connector 600 is directly aligned with the positioning hole 231 of the SC connection port 230. The connection method is well-known in the prior art and, therefore, is not further described herein.

It should be noted that the adapter uses the positioning block and the bottom plate to connect with the positioning hole and the grooves on the SC connection port. Therefore, the connection element is not a necessity. On the other hand, if one wants to enhance the connection between the adapter and the SC connection port by using the connection element, the connection method between the first cover and the second cover can be utilized. For example, both side plates of the adapter can be formed with a hook hole (or the hook holes can be formed at the original position for the block). The hook arms of the connection element catch the hook holes. Alternatively, one can interchange the positions of the hook arms and the hook holes. Furthermore, there are many other choices for the combination of the first cover and the second cover. For example, the positions of the pinhole and the pin can be interchanged, or the positions of the block and the plugging hole can be interchanged too. Moreover, the invention can be applied to both single-mode and multi-mode optic fibers.

According to the spirit of the invention, a plugging-type adapter is designed for the first-type connection port of an optical transceiver housing. The adapter is attached to the first-type connection port of the housing and has a second-type connection port for a second-type connector to be plugged in. When the adapter is removed, the connection module can still connect with the same first-type connectors. The above-mentioned first-type and second-type specifications can be selected from the LC, SC, and MU standards mentioned in Field of the Invention and other ST, MTP, FJ or new small-form-factor (SFF) standards, such as MT-RJ (AMP, Inc.) and VF-45 (3M, Inc.).

Certain variations would be apparent to those skilled in the art, which variations are considered within the spirit and scope of the claimed invention.

What is claimed is:

1. An optical transceiver connection module for an optical transceiver to connect with different types of fiber connectors, the optical transceiver connection module comprising:
a housing, which covers the optical transceiver and has a first-type connection port for connection with a first-type connector; and
an adapter, which has a second-type connection port for connection with a second-type connector and is attached to the first-type connection port of the housing.

2. The optical transceiver connection module of claim 1 further comprising a connection element for the adapter to be plugged in from one side opposite to the second-type connection port.

3. The optical transceiver connection module of claim 1, wherein the first-type standard is selected from the group consisting of LC, SC, MU, ST, MTP, FJ, MT-RJ, and VF-45 standards.

4. The optical transceiver connection module of claim 1, wherein the second-type standard is selected from the group consisting of LC, SC, MU, ST, MTP, FJ, MT-RJ, and VF-45 standards.

5. An optical transceiver connection module for an optical transceiver to connect with different types of fiber connectors, the optical transceiver connection module comprising:
a housing, which includes a first cover and a second cover for covering the optical transceiver and has a first-type connection port for connection with a first-type connector; and
an adapter, which has a second-type connection port for connection with a second-type connector and is attached to the first-type connection port of the housing.

6. The optical transceiver connection module of claim 5, wherein one input terminal of the first-type connection port has a positioning hole and the adapter is formed with a corresponding positioning block.

7. The optical transceiver connection module of claim 5, wherein two opposite grooves are formed on the inner side of the first-type connection port and the adapter is formed with a bottom plate that are matched with the two grooves.

8. The optical transceiver connection module of claim 5 further comprising a connection element for the adapter to be plugged in from the opposite side of the second-type connection port.

9. The optical transceiver connection module of claim 8, wherein the connection element has a plate with a through hole on one side and extending out at least one hook arm, the tail of the hook arm having a hook and the adapter having at least one protruding block for the hook arms to hold.

10. The optical transceiver connection module of claim 8, wherein the connection element has a plate with a through hole on one side and extending out at least one hook arm, the tail of the hook arm having a hook and the adapter having at least one hook hole for the hook arms to hold.

11. The optical transceiver connection module of claim 8, wherein the connection element has a plate with a through hole on one side and extending out at least one hook arm, the tail of the hook arm having a hook and the adapter extending out at least one side plate with hook holes for the hook arms to hold.

12. The optical transceiver connection module of claim 8, wherein the connection element has a plate with a through hole on one side and at least one hook hole, the adapter extends out at least one side plate with at least one hook arm, the tail of the hook arm having a hook to hold the hook hole.

13. The optical transceiver connection module of claim 5, wherein the first cover has at least one pin extending toward the second cover, the tail of the pin being a hook, and the second cover has at least one pinhole for the pin to hold.

14. The optical transceiver connection module of claim 5, wherein the second cover has at least one pin extending toward the second cover, the tail of the pin being a hook, and the first cover has at least one pinhole for the pin to hold.

15. The optical transceiver connection module of claim 5, wherein the first cover is installed with the first-type connection port on one side.

16. The optical transceiver connection module of claim 15, wherein the first-type connection port is formed with a protruding block, the second cover extends a fin on one side, and the fin is formed with a plugging hole that matches with the protruding block.

17. The optical transceiver connection module of claim 15, wherein the first-type connection port has a plugging hole, the second cover extends a fin on one side, and the fin is formed with a protruding block that matches with the plugging hole.

18. The optical transceiver connection module of claim 5, wherein an optic cable connected to the first-type connector and the second-type connector encloses a plurality of optic fibers selected from the group consisting of single-mode and multi-mode optic fibers.

19. The optical transceiver connection module of claim 5, wherein the first-type standard is selected from the group consisting of LC, SC, MU, ST, MTP, FJ, MT-RJ, and VF-45 standards.

20. The optical transceiver connection module of claim 5, wherein the second-type standard is selected from the group consisting of LC, SC, MU, ST, MTP, FJ, MT-RJ, and VF-45 standards.
